(19) United States
(12) Patent Application Publication
(10) Pub. No.: US 2025/0021005 A1
(43) Pub. Date: Jan. 16, 2025

(54) SYSTEM AND METHOD FOR REDUCING EXTREME ULTRAVIOLET (EUV) VESSEL TIN DEPOSITION

(71) Applicant: Taiwan Semiconductor Manufacturing Company, Ltd., Hsinchu (TW)

(72) Inventors: Chia-Wei Wang, Taichung City (TW); Po-Ming Shih, Hsinchu (TW)

(21) Appl. No.: 18/350,750

(22) Filed: Jul. 12, 2023

(51) Int. Cl. G03F 7/20

(52) U.S. Cl. CPC G03F 7/2006; G03F 7/201; G03F 7/2037

(57) ABSTRACT

A method for extreme ultraviolet (EUV) lithography includes generating target droplets and using a first laser source to generate laser pulses to heat the target droplets to generate extreme ultraviolet (EUV) light and a plurality of particles. The method also includes using a supplemental laser source to generate laser pulses to ionize the plurality of particles, applying a magnetic field to direct ionized particles to debris collection device, and capturing the ionized particles by the debris collection device.

### BACKGROUND

An advanced technology used in semiconductor manufacturing is Extreme Ultraviolet (EUV) lithography. EUV uses scanners that use light in the extreme ultraviolet spectrum of electromagnetic radiation, including wavelengths from about one nanometer (nm) to about one hundred nanometers. Many EUV scanners still utilize projection printing, similar to various earlier optical scanners, except that EUV scanners implement it using reflective rather than refractive optics, i.e., using mirrors rather than lenses.

EUV lithography uses a laser-produced plasma that emits ultraviolet light. Laser-generated plasma is generated by using carbon dioxide (CO₂) laser beams or similar high power laser beams, such as laser beams and the like, are focused onto small fuel droplet targets of tin (Sn) in order to convert them into a highly ionized plasma state. The laser-generated plasma emits extreme ultraviolet light having a maximum emission peak of about 13.5 nm or less. The extreme ultraviolet light is then collected by a collector and reflected by optics toward a lithographic exposure object, such as a semiconductor wafer. Tin debris is generated during this process, which can adversely affect the performance and efficiency of the EUV apparatus.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of an extreme ultraviolet (EUV) lithography system, in accordance with some embodiments.

FIG. 2 is a schematic view illustrating a radiation source, in accordance with some embodiments.

FIG. 3 is a simplified schematic diagram illustrating an apparatus for extreme ultraviolet lithography, according to some embodiments.

FIG. 4 is a simplified schematic diagram illustrating an apparatus for extreme ultraviolet lithography, according to some embodiments.

FIG. 5 is a simplified schematic diagram illustrating an apparatus for extreme ultraviolet lithography, according to some embodiments.

FIG. 6 is a simplified schematic diagram illustrating an apparatus for extreme ultraviolet lithography, according to some embodiments.

FIG. 7 is a simplified schematic diagram illustrating an apparatus for extreme ultraviolet lithography, according to some embodiments.

FIG. 8 is a simplified flowchart illustrating a method for extreme ultraviolet (EUV) lithography, according to some embodiments.

FIGS. 9A and 9B illustrate a computer system for controlling a lithography system, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Furthermore, the term “made of” can mean either “including” or “consisting of”. In the present disclosure, the term “one of A, B, and C” means “A, B, and/or C” (A, B, C, A and B, A and C, B and C, or A, B, and C), and unless otherwise specified, does not mean one element from A, one element from B, and one element from C.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

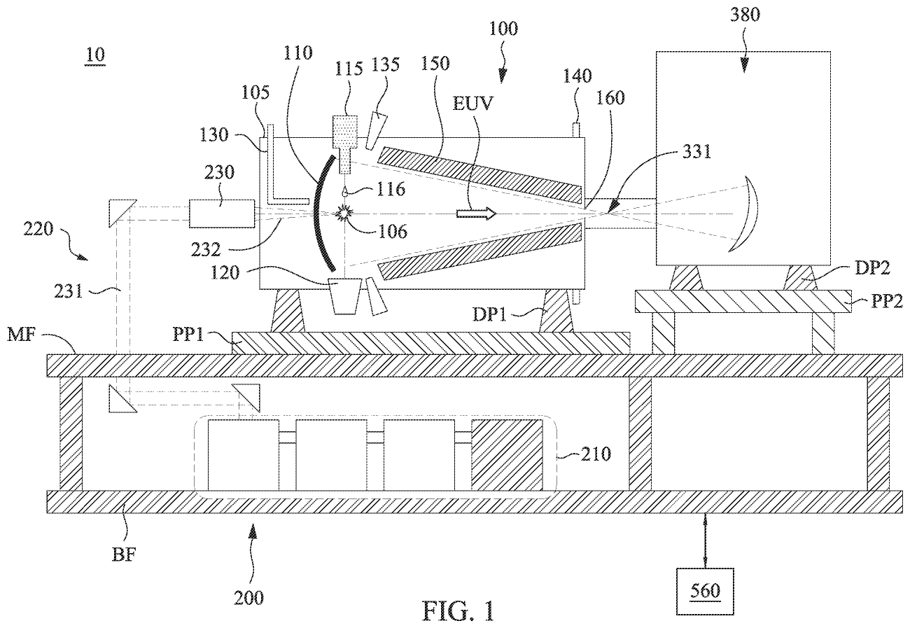

FIG. 1 is a schematic view of an extreme ultraviolet (EUV) lithography system 10. The EUV lithography system 10 includes an EUV radiation source apparatus 100 for generating EUV light; an exposure tool 380, such as a scanner; and an excitation laser source apparatus 200. As illustrated in FIG. 1, in some embodiments, the extreme ultraviolet radiation source apparatus 100 and the exposure tool 380 are installed on a main floor MF of a clean room, and the excitation laser source apparatus 200 is installed in a base floor BF located below the main floor ME. The respective extreme ultraviolet radiation source apparatus 100 and the exposure tools 380 are placed on the base plates PP1 and PP2 via the dampers DP1 and DP2, respectively. The EUV radiation source apparatus 100 and the exposure tool 380 are coupled to each other at a connection point 331 by a coupling mechanism, which may comprise a focusing unit (not shown).

The extreme ultraviolet lithography system 10 is designed to expose the resist layer to extreme ultraviolet light (or EUV radiation). The resist layer is a material sensitive to extreme ultraviolet light. The extreme ultraviolet lithography system 10 employs an extreme ultraviolet radiation source apparatus 100 to generate extreme ultraviolet light having a wavelength range between about 1 nanometer (nm) and about 100 nm. In one particular example, the extreme ultraviolet radiation source apparatus 100 generates extreme ultraviolet light having a wavelength centered at about 13.5 nanometers. In various embodiments, the extreme ultraviolet radiation source apparatus 100 generates plasma using a laser to generate EUV radiation.

As illustrated in FIG. 1, the extreme ultraviolet radiation source apparatus 100 comprises a target droplet generator 115 and a laser-produced plasma collector 110, surrounded by a chamber 105. Target droplet generator 115 generates a plurality of target droplets 116. In some embodiments, target droplets 116 are tin (Sn) droplets. In some embodiments, target droplets 116 have a diameter of about 30 micrometers (μm). In some embodiments, target droplets 116 are generated at a rate of about fifty droplets per second and introduced into excitation zone 106 at a velocity of about seventy meters per second (m/s or mps). Other materials may also be used for target droplets 116, for example, liquid materials such as eutectic alloys containing Sn and lithium (Li).

As target droplets 116 move through excitation zone 106, a pre-pulse of laser light (not shown) first heats target droplets 116 and converts them into a target plume of lower density (target plumes). Next, a main pulse 232 of laser light is directed through a window or lens (not shown) into the excitation zone 106 to convert the target plume into a laser-generated plasma. The window or lens is composed of a suitable material that is substantially transparent to the pre-pulse and the main pulse 232 of the laser. The generation of the pre-pulse and the main pulse 232 is synchronized with the generation of the target droplet 116. In various embodiments, the pre-pulse laser pulse has a spot size of about 100 μm or less, and the main pulse 232 has a spot size of about 200 μm to about 300 μm. The delay between the pre-pulse and the main pulse 232 is controlled to allow the target plume to form and expand to the optimal size and geometry. When the main pulse 232 heats the target plume, a high temperature plasma is generated. The laser-produced plasma emits EUV radiation, which is collected by one or more mirrors of the laser-produced plasma collector 110. More specifically, the laser-produced plasma collector 110 has a reflective surface that reflects and focuses EUV radiation for use in a lithographic exposure process. In some embodiments, the droplet catcher 120 is mounted opposite the target droplet generator 115. For example, when one or more target droplets 116 are intentionally or otherwise missed by the pre-pulse or main pulse 232, the droplet catcher 120 may be used to catch the excess target droplets 116.

As illustrated, the target droplet generator 115 generates tin droplets along the longitudinal axis. Each target droplet 116 is struck by the CO₂ laser pre-pulse. During travel along the longitudinal axis, the droplet will responsively change its shape to a “pie shape”. After a certain duration (delay time from main pulse 232 to pre-pulse), target droplets 116 are entrained by the CO₂ laser near the primary focus point (PF). The main pulse 232 hits in order to generate extreme ultraviolet light pulses. Next, the EUV light pulse is collected by the laser-produced plasma collector 110 and delivered to the scanner side for wafer exposure.

The laser-produced plasma collector 110 comprises suitable coating materials and shapes to act as EUV collecting, reflecting, and focusing mirrors. In some embodiments, the laser-produced plasma collector 110 is designed to have an elliptical geometry. In some embodiments, the coating material of laser-produced plasma collector 110 is similar to the reflective multilayer of an EUV mask. In some examples, the coating material of the laser-produced plasma collector 110 comprises a plurality of layers, such as a plurality of molybdenum/silicon (Mo/Si) double layers, and may further comprise a capping layer, such as ruthenium (Ru), coated on the plurality of layers to substantially reflect EUV light.

The main pulse 232 is generated by exciting the excitation laser source apparatus 200. In some embodiments, the excitation laser source apparatus 200 includes a preheat laser and a main laser. The preheat laser generates a pre-pulse that is used to heat or preheat the target droplets 116 in order to create a low density target plume that is subsequently heated (or reheated) by the main pulse 232, resulting in increased EUV light emission.

The excitation laser source apparatus 200 may include a laser generator 210, laser guiding optics 220, and a focusing apparatus 230. In some embodiments, laser generator 210 contains a carbon dioxide (CO₂) laser source or a doped neodymium yttrium aluminum garnet (Nd:YAG) laser source. Laser light 231 generated by the laser generator 210 is guided by the laser guiding optics 220 and focused by the focusing apparatus 230 into a main pulse 232 of excitation laser light and then introduced into the extreme ultraviolet radiation source apparatus 100 through one or more apertures, such as windows or lenses as described previously.

In this extreme ultraviolet radiation source apparatus 100, the laser-generated plasma generated by the main pulse 232 creates physical debris, such as ions, gases, and atoms of the target droplet 116, along with the desired extreme ultraviolet light. In operation of the EUV lithography system 10, there is an accumulation of such physical debris on the laser-produced plasma collector 110, and such physical debris can exit the chamber 105 and enter the exposure tool 380 (i.e., the “scanner side”).

In various embodiments, the buffer gas is supplied from the first buffer gas source 130 through an aperture in the laser-produced plasma collector 110 through which the main pulse 232 of the laser is delivered to the target droplet 116. In some embodiments, the buffer gas is hydrogen (H₂), Helium (He), argon (Ar), nitrogen (N₂), or another inert gas. In some embodiments, H₂ is used because H radicals generated by ionization of the buffer gas may also be used for cleaning purposes. Further, H₂ absorbs the least amount of EUV light generated on the source side and, therefore, absorbs the least light used for semiconductor manufacturing operations performed on the scanner side of the EUV lithography system 10. A buffer gas may also be provided by one or more second pulse gas supplies 135 towards the laser-produced plasma collector 110 and/or around the edges of the laser-produced plasma collector 110. Further, as described in more detail below, the chamber 105 includes one or more gas outlets 140 to buffer the discharge of buffer gas outside the chamber 105.

Hydrogen has a low absorption for EUV radiation. The hydrogen gas reaching the coating surface of the laser-produced plasma collector 110 chemically reacts with the metal of the target droplets 116, thereby forming hydrides, e.g., metal hydrides. When Sn is used as the target droplets 116, stannane (SnH₄) is formed as a gaseous byproduct of the EUV generation process. Gaseous SnH₄ is then pumped out through outlet 140. However, it is difficult to evacuate all gaseous SnH₄ from the chamber 105 and prevent Sn debris and gaseous SnH₄ from getting into the exposure tool 380 and excite the excitation laser source apparatus 200. To capture Sn, SnH₄, or other debris, one or more debris collection mechanisms or devices 150 are employed in the chamber 105. In various embodiments, the controller 560 controls the extreme ultraviolet lithography system 10 and/or one or more components thereof previously illustrated and described with reference to FIG. 1.

A large amount of tin debris is generated at a high rate during EUV exposure. A scrubber in coordination with high density H₂ may remove most of the tin debris. However, a part of Sn particles may be separated from H₂ and reach the interface between the source and the scanner chamber. Then, in various embodiments, the Sn particles may be accelerated toward the mask plate by the high pressure.

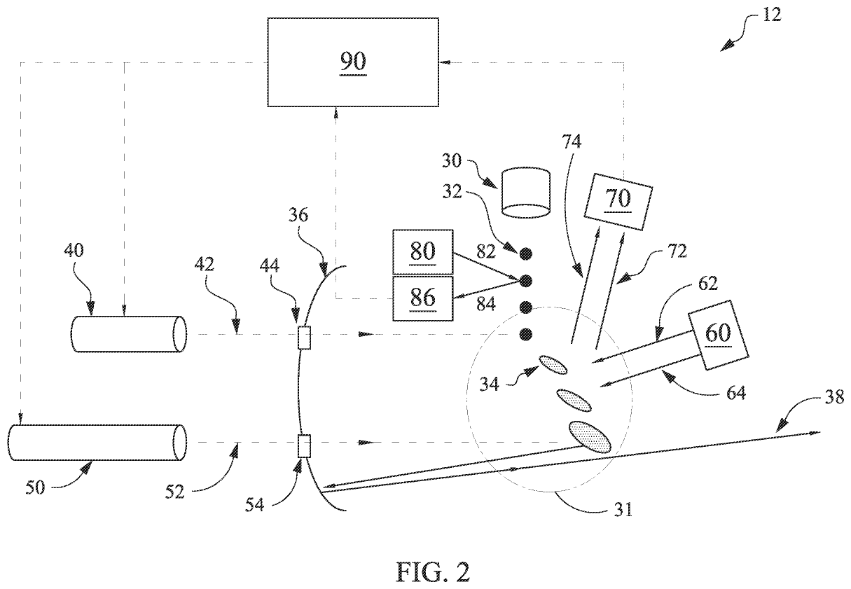

FIG. 2 is a schematic view illustrating a radiation source 12, in accordance with some embodiments. The radiation source 12 is similar to the EUV radiation source apparatus 100 described above in connection with FIG. 1. As shown in FIG. 2, radiation source 12 employs a dual-pulse laser-produced plasma (LPP) mechanism to generate plasma and further generate EUV radiation from the plasma.

Referring to FIG. 2, the radiation source (or EUV source) 12 includes a target droplet generator 30, a first laser source 40, a second laser source 50, an LPP collector 36, a first laser beam generator 60 configured to produce laser beams 62 and 64, a first laser beam monitor 70 configured to receive the reflected laser beams 72 and 74, a second laser beam generator 80, a second laser beam monitor 86, and a controller 90. The components of the radiation source 12 are further described below.

The target droplet generator 30 is configured to generate target droplets 32. In an embodiment, the target droplets 32 are tin (Sn) droplets, i.e., droplets having tin or tin-containing material(s) such as eutectic alloy containing tin, lithium (Li), and xenon (Xe). In an embodiment, each of the target droplets 32 has a diameter about 30 microns (m). In an embodiment, the target droplets 32 are generated at a rate of about 50 kilohertz (kHz) and are introduced into a zone of excitation 31 in the radiation source 12 at a speed of about 70 meters per second (m/s).

The first laser source 40 is configured to produce pre-pulses 42. The second laser source 50 is configured to produce main pulses 52. In the present embodiment, the pre-pulses 42 have less intensity and smaller spot size than the main pulses 52. Therefore, the pre-pulses 42 are also referred to as the pre-pulses, and the main pulses 52 as the main pulses. The pre-pulses 42 are used to heat (or pre-heat) the target droplets 32 to create low-density target plumes 34, which are subsequently heated (or reheated) by corresponding main pulses 52, generating increased emission of EUV radiation 38. In the present embodiment, a main pulse 52 is said to be “corresponding” to a pre-pulse 42 when a target plume 34 produced by the pre-pulse 42 is heated by the main pulse 52. The EUV radiation 38 is collected by the collector 36. The collector 36 further reflects and focuses the EUV radiation 38 for the lithography exposing processes, such as illustrated in FIG. 1. In an embodiment, a droplet catcher (not shown) is installed opposite the target droplet generator 30. The droplet catcher is used for catching excessive target droplets 32. For example, some target droplets 32 may be purposely missed by both the pre-pulses 42 and the main pulses 52.

The collector 36 is designed with proper coating material and shape, functioning as a mirror for EUV collection, reflection, and focus. In some embodiments, the collector 36 is designed to have an ellipsoidal geometry. In some embodiments, the coating material of the collector 36 is similar to the reflective multi-layer of the EUV mask. In some examples, the coating material of the collector 36 includes a multi-layer (ML), such as a plurality of Mo/Si film pairs, and may further include a capping layer (such as Ru) coated on the ML to substantially reflect the EUV radiation 38. In some embodiments, the collector 36 may further include a grating structure designed to effectively scatter the laser beams and laser pulses directed onto the collector 36. For example, a silicon nitride layer is coated on the collector 36 and is patterned to have a grating pattern. One consideration in an EUV lithography system is the usable lifetime of the collector 36. During the EUV generation processes, the reflective surface of the collector 36 is subjected to the impact of various particles, ions, and radiation. Over time, the reflectivity of the collector 36 degrades due to particle accumulation or deposition, ion damages, oxidation, blistering, etc. Among these, particle (e.g., tin debris) deposition is a dominant factor.

In various embodiments, the pre-pulses 42 have a spot size of about 100 μm or less, and the main pulses 52 have a spot size of about 200 μm to 300 μm, such as 225 μm. The pre-pulses 42 and the main pulses 52 are generated to have certain driving powers to fulfill wafer volume production, such as a throughput of 125 wafers per hour. In an embodiment, the pre-pulses 42 are equipped with about 2 kilowatts (kW) driving power, and the main pulses 52 are equipped with about 19 kW driving power. In various embodiments, the total driving power of the pre-pulses 42 and the main pulses 52 is at least 20 kW, such as 27 kW. In an embodiment, the first laser source 40 is a carbon dioxide (CO₂) laser source. In another embodiment, the first laser source 40 is a neodymium-doped yttrium aluminum garnet (Nd:YAG) laser source. In an embodiment, the second laser source 50 is a CO₂ laser source.

The pre-pulses 42 and main pluses 52 are directed through windows (or lens) 44 and 54, respectively, into the zone of excitation 31. The windows 44 and 54 adopt a suitable material substantially transparent to the respective laser pulses. The pre-pulses 42 and main pulses 52 are directed towards the target droplets 32 and target plumes 34 at proper angles for optimal EUV conversion efficiency. For example, the pre-pulses 42 may be aligned to interact with the target droplets 32 at an angle of a few degrees (e.g., 5 degrees) off-normal. The main pulses 52 are also properly aligned with the target plumes 34 for maximum EUV conversion efficiency.

The generation of the pre-pulses 42 and main pulses 52 are synchronized with the generation of the target droplets 32. In an embodiment, the synchronization is achieved by utilizing the second laser beam generator 80 and the second laser beam monitor 86. The second laser beam generator 80 is configured to produce a laser beam 82 that is directed to the travel path of the target droplets 32. When a target droplet 32 moves along the path, the laser beam 82 is reflected by the target droplet 32 and the reflected laser beam 84 is received by the second laser beam monitor 86, which notifies the controller 90 about the presence of the target droplet 32. The controller 90 in turn notifies the first laser source 40 to set off a trigger for generating the pre-pulse 42. In an embodiment, the second laser beam monitor 86 may notify the laser source 40 directly without involving the controller 90.

In the present embodiment, the first laser beam generator 60 and the first laser beam monitor 70 are configured to monitor the speed of the target plumes 34 along the Z direction. The monitored speed is utilized by the controller 90 for adjusting the energy level of the pre-pulses 42, the energy level of the main pulses 52, the delay between the pre-pulses 42 and the corresponding main pulses 52, other parameters of the first and second laser sources 40 and 50, or combinations thereof. By optimizing one or more of the above parameters, the EUV conversion efficiency of the radiation source 12 and the lifetime of the collector 36 can both be improved.

In various embodiments, the tin debris reaches a velocity of 1000 to 2000 m/s during the extreme ultraviolet light generating process. In addition, the hydrogen purge gas may cause sputtering of tin particles that accumulate on the source-side chamber walls. In various embodiments, these particles can become airborne at a velocity of 100 to 200 m/s. Furthermore, these particles reach high momentum due to the pressure difference between the source side and the scanner side. The momentum of the Sn particles into the intermediate focus 160 shown in FIG. 1 is therefore very large. Such particles can reach speeds and velocities of 1000 m/s or more and nominal momentum of up to about 3.67×10⁻¹⁶ kg*m/s. In some embodiments, particles migrating to the scanner side due to pressure differences fall on the mask plate and the wafer, thereby deleteriously leading to a higher incidence of defects in semiconductor manufacturing operations performed by the EUV lithography system 10.

The method and apparatus described herein help reduce tin debris on the surface of the collector 36 shown in FIG. 2, and other parts, such as a tin-on-mask defect, which increases repair cost and reduce productivity.

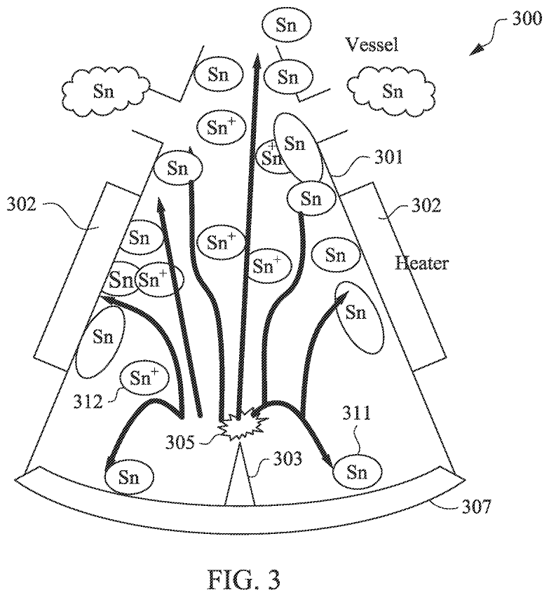

FIG. 3 is a simplified schematic diagram illustrating an apparatus for extreme ultraviolet lithography, according to some embodiments. As shown in FIG. 3, apparatus 300 is a radiation source (also referred to as radiation source 300) that can be used in an EUV lithography system, such as the EUV lithography system 10 in FIG. 1. Apparatus 300 includes components similar to those in EUV radiation source 100 described above in connection with FIG. 1 and radiation source 12 described above in connection with FIG. 2. Some of those components are not shown in FIG. 3 to simplify the drawing.

As shown in FIG. 3, radiation source 300 includes a vessel 301, a heater 302 surrounding the vessel 301, a first laser source 303, an excitation zone 305, and a EUV light collector 307 (sometimes also referred to as a “collector” or a “laser-produced plasma collector”). Heater 302 is used to maintain the vessel at a desired temperature. Heater 302 also functions as a debris collection device, similar to the debris collection mechanisms or devices 150 depicted in FIG. 1. A first laser source 303 can generate pre-pulses and main pulses (not shown), similar to the pre-pulses and main pulses described above in connection with FIGS. 1 and 2. In the embodiment shown in FIG. 3, the first laser source 303 is an excitation laser source apparatus like the excitation laser source apparatus 200 shown in FIG. 1, which may include a preheat laser and a main laser, as discussed above. In other embodiments, the first laser source 40 and the second laser source 50, as shown in FIG. 2, may be used instead of the excitation laser source apparatus 200 shown in FIG. 1, which integrates a preheat laser and a main laser. A person of ordinary skill in the art would recognize other variations, modifications, and alternatives as long as pre-pulses and main pulses (e.g., main pulses 232 shown in FIG. 1) are generated accordingly. The pre-pulses are used to heat (or pre-heat) the target droplets in the excitation zone 305 to create low-density target plumes, which are subsequently heated (or reheated) by corresponding main pulses, generating increased emission of EUV radiation. EUV light collector 307 reflects and focuses the EUV radiation for the lithography exposing processes, similar to laser-produced plasma collector 110 in FIG. 1 and laser-produced plasma (LPP) collector 36 in FIG. 2.

In the example of FIG. 3, the target droplets (not shown) are tin (Sn) droplets, i.e., droplets having tin or tin-containing material(s) such as eutectic alloy containing tin, lithium (Li), and xenon (Xe). After being struck by the laser, some tin (Sn) particles remain in the vessel. FIG. 3 also shows tin (Sn) particles, including Sn particles 311 and Sn ions (labeled as Sn⁺ in FIG. 3) 312. During the EUV generation processes, the reflective surface of the collector 307 is subjected to the impact of various particles, ions, and radiation. Over time, the reflectivity of the collector 307 degrades due to particle accumulation, ion damages, oxidation, and blistering, etc. Among these, particle (e.g., tin debris) deposition is a dominant factor. In addition, tin particles have also been found on the cap and walls of the vessel 301. The tin particle deposits and contamination on the EUV lithography system 10 shown in FIG. 1 can decrease the efficiency of the EUV lithography system 10 and increase cost and productivity. Tin particles have also been found to escape the vessel and deposit on the EUV masks used in lithography, thereby directly impacting yield and cost.

Some embodiments are configured to reduce EUV vessel tin deposition by tin ionized and reflux system, as will be described below.

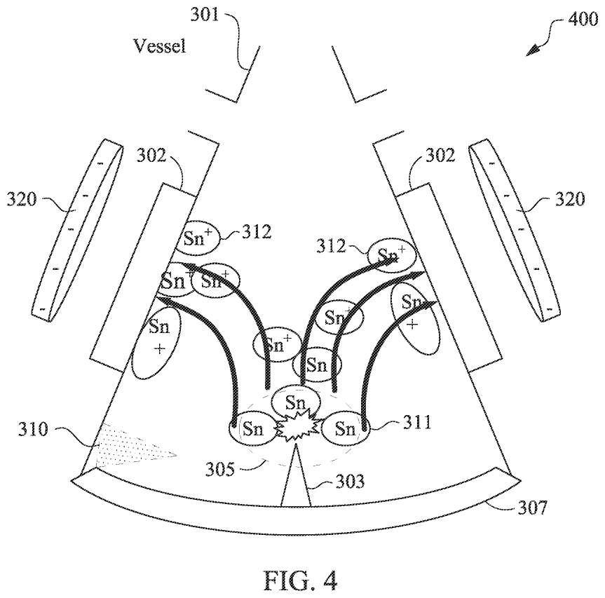

FIG. 4 is a simplified schematic diagram illustrating an apparatus 400 for extreme ultraviolet lithography, according to some embodiments. As shown in FIG. 4, apparatus 400 is a radiation source (also referred to as radiation source 400) that can be used in an (EUV) lithography system (e.g., the EUV lithography system 10 shown in FIG. 1). Radiation source 400 has similar components as radiation source 300 described above in connection to FIG. 3, and these components are labeled with the same reference numerals. As shown in FIG. 4, radiation source 400 includes a vessel 301, a heater 302 disposed adjacent to the vessel 301, a first laser source 303, an excitation zone 305, and an EUV light collector 307. The functions of these components are similar to the corresponding components as those described above in connection with FIG. 3. Specifically, in the embodiment shown in FIG. 4, the first laser source 303 is an excitation laser source apparatus like the excitation laser source apparatus 200 shown in FIG. 1, which may include a preheat laser and a main laser, as discussed above. In other embodiments, the first laser source 40 and the second laser source 50, as shown in FIG. 2, may be used instead of the excitation laser source apparatus 200 shown in FIG. 1, which integrates a preheat laser and a main laser. A person of ordinary skill in the art would recognize other variations, modifications, and alternatives as long as pre-pulses and main pulses (e.g., main pulses 232 shown in FIG. 1) are generated accordingly.

In some embodiments, radiation source 400 further includes a supplemental laser source 310 and a magnetic source 320 configured to reduce the Sn particles. In some embodiments, the supplemental laser source 310 produces pulsed laser to strike the Sn particles 311 located, for example, in the excitation zone 305 to ionize the Sn particles 311 into Sn ions 312. The Sn particles 311 would otherwise remain not ionized without the supplemental laser source 310. Therefore, the laser pulses generated by the supplemental laser source 310 can increase the percentage of Sn particles 311 that are ionized, thereby reducing the percentage of Sn particles that are not ionized. As will be discussed below, the Sn ions 312 are directed to the heaters 302. In some embodiments, the pulsed laser is generated by the supplemental laser source 310 after the main pulses (e.g., the main pulses 232 shown in FIG. 1) heats the target plume and a high temperature plasma is generated accordingly. In other embodiments, the pulsed laser may be generated by the supplemental laser source 310 constantly. In some embodiments, the pulsed laser generated by the supplemental laser source 310 may be directed at different locations over time to best ionize Sn particles 311.

The magnetic source 320 includes electromagnets disposed adjacent to heaters 302 and produces a magnetic field to direct the Sn ions 312 to the heaters 302. In other embodiments, the magnetic source 320 includes at least one coil of wire with electric current running through it. In some embodiments, the magnetic source 320 includes a pair of magnets. In other embodiments, the magnetic source 320 includes more than two magnets. By manipulating the magnetic field generated by the magnetic source 320, the trajectories of the Sn ions 312 can be adjusted, so that a large portion of the Sn ions 312 can hit the heater 302. Heater 302 also functions as a debris collection device, similar to the debris collection mechanisms or devices 150 depicted in FIG. 1. The heater 302 generates heat to vaporize the Sn particles 311 (Sn ions 312 become Sn particles 311 after they hit the chamber sidewall or the vessel 301) at close proximity to the heater 302, thereby facilitating the reflux of the Sn particles 311. As a result, the amount of Sn particles 311 accumulated on the chamber walls or the vessel 301 is reduced, leading to reduced Sn debris.

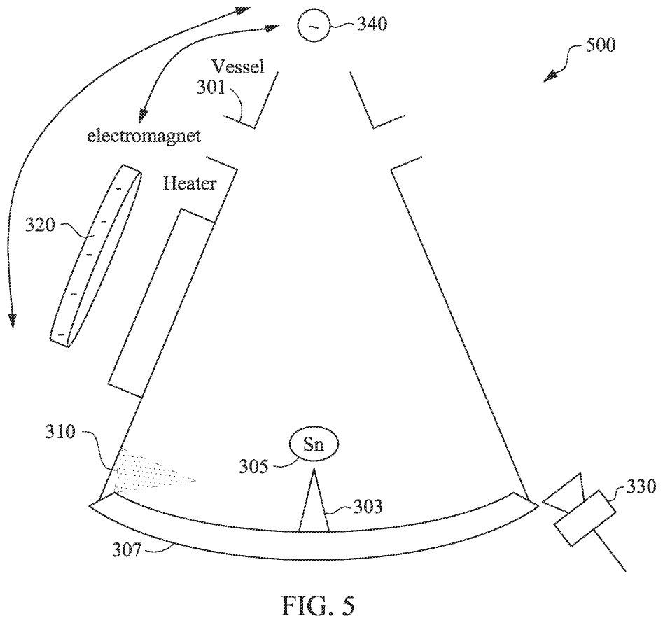

FIG. 5 is a simplified schematic diagram illustrating an apparatus 500 for extreme ultraviolet lithography, according to some embodiments. As shown in FIG. 5, apparatus 500 is a radiation source (also referred to as radiation source 500) that can be used in an EUV lithography system like the EUV lithography system 10 shown in FIG. 1. Radiation source 500 has similar components as radiation source 400 described above in connection to FIG. 4, and these components are labeled with the same reference numerals. As shown in FIG. 5, radiation source 500 includes a vessel 301, a heater 302 adjacent to the vessel 301, a first laser source 303, an excitation zone 305, and an EUV light collector 307. Like radiation source 400 in FIG. 4, radiation source 500 also includes a supplemental laser source 310, which provides laser pulses (sometimes referred to as “third laser pulses” as compared to pre-pulses and main pulses as discussed above with reference to FIG. 1), and a magnetic source 320, which generates a magnetic field, configured to direct Sn ions 312 shown in FIG. 4.

The functions of these components are similar to the corresponding components as those described above in connection to FIG. 4. For example, the supplemental laser source 310 produces laser pulses to strike the Sn particles 311 shown in FIG. 4 to ionize the Sn particles 311 into Sn ions 312 shown in FIG. 4. In some embodiments, the magnetic source 320 includes electromagnets disposed adjacent to heaters 302 and produces a magnetic field to direct the Sn ions 312 to the heaters 302. The heaters 302 also function as a debris collection device, as discussed above in conjunction with FIG. 4.

In addition, radiation source 500 further includes a CCD module (charge-coupled device module) 330 for monitoring the Sn debris and an electromagnet management module 340. Although the CCD module 330 is described in the embodiment shown in FIG. 5, it should be understood that other suitable debris imaging feedback systems may be employed in other embodiments. In one embodiment, the debris imaging feedback system include complementary metal oxide semiconductor (CMOS) image sensors, which include, among other components, micro-lens, photodiodes, and color filters. The electromagnet management module 340 on the vessel manages the electromagnet to control the magnetic fields based on feedback information from the supplemental laser source 310 and the CCD module 330. In one implementation, the magnetic source 320 includes at least one coil of wire with electric current running through it, and the electromagnet management module 340 includes, among other components, a current source, which generates the electric current running through the coil of wire. By fine-tuning the electric current, the amplitude of the magnetic field generated by the magnetic source 320 is adjusted accordingly. Based on the feedback information from the supplemental laser source 310 and the CCD module 330, the magnetic field is adjusted accordingly, so that a large portion of the Sn ions (e.g., Sn ions 312 shown in FIG. 4) are directed toward the heaters 302.

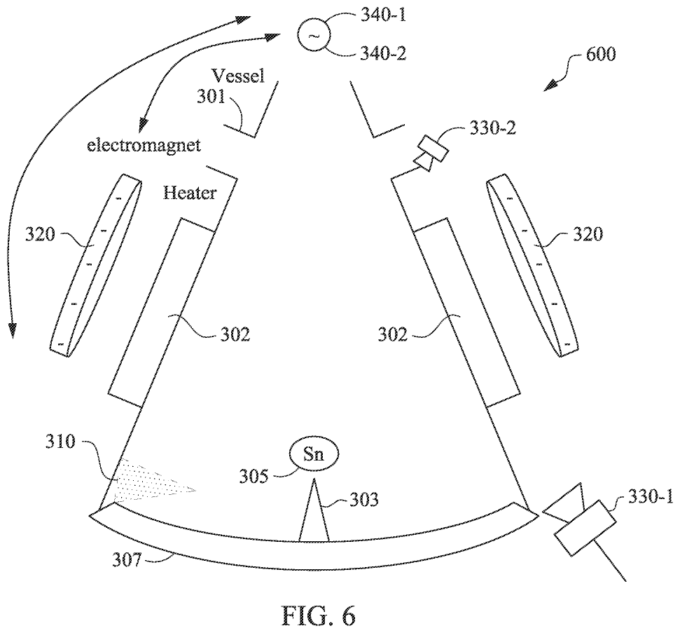

FIG. 6 is a simplified schematic diagram illustrating an apparatus 600 for extreme ultraviolet lithography, according to some embodiments. As shown in FIG. 6, apparatus 600 is a radiation source (also referred to as radiation source 600) that can be used in an EUV lithography system like the EUV lithography system 10 shown in FIG. 1. Radiation source 600 has similar components as radiation source 500 described above in connection to FIG. 5, and these components are labeled with the same reference numerals. As shown in FIG. 6, radiation source 600 has a vessel 301, a heater 302 surrounding the vessel 301, a first laser source 303, an excitation zone 305, and an EUV light collector 307. Like radiation source 500 in FIG. 5, radiation source 600 also includes a supplemental laser source 310, which provides a laser pulse, and a magnetic source 320 configured to produce magnetic field.

The functions of these components are similar to the corresponding components as those described above in connection to FIG. 5. For example, the supplemental laser source 310 produces laser pulses (sometimes referred to as “third laser pulses” as compared to pre-pulses and main pulses as discussed above with reference to FIG. 1) to strike the Sn particles 311 shown in FIG. 4 to ionize the Sn particles 311 into Sn ions 312 shown in FIG. 4. In some embodiments, the magnetic source 320 includes electromagnets disposed adjacent to heaters 302 and produces a magnetic field to direct the Sn ions 312 to the heaters 302. In this case, the heater 302 also functions as a debris collection device, as discussed above in conjunction with FIG. 4.

In addition, radiation source 600 further includes at least two CCD modules 330-1 and 330-2 (collectively 330) for monitoring the Sn debris. The first CCD module 330-1 and the second CCD module 330-2 are directed toward different regions of the vessel 301, thereby decreasing the impact of debris variation across the vessel 301. Although only two CCD modules 330-1 and 330-2 are shown in FIG. 6, one of ordinary skill in the art would recognize that more than two CCD modules 330 can be employed in other embodiments if necessary to increase monitoring accuracy. The radiation source 600 also has at least two electromagnet management modules 340-1 and 340-2 on the vessel that detect and manage the Sn debris collection based on feedback information from the third pulsed laser produced by the supplemental laser source 310 and CCD modules 330-1 and 330-2. This information may represent data collected in different areas in the vessel (i.e., by area in the vessel). Each of the two electromagnet management modules 340-1 and 340-2 includes, among other components, a current source, which generates the electric current running through the coil of wire of the corresponding magnetic source 320. By fine-tuning the electric current, the amplitude of the magnetic field generated by each magnetic source 320 is adjusted accordingly. As a result, a large portion of the Sn ions (e.g., Sn ions 312 shown in FIG. 4) are directed toward the heaters 302. By having separate electromagnet management modules 340-1 and 340-2, multiple magnetic fields can be adjusted separated and independently, thereby achieving elevated latitude of manipulating the trajectories of the Sn ions 312 shown in FIG. 4.

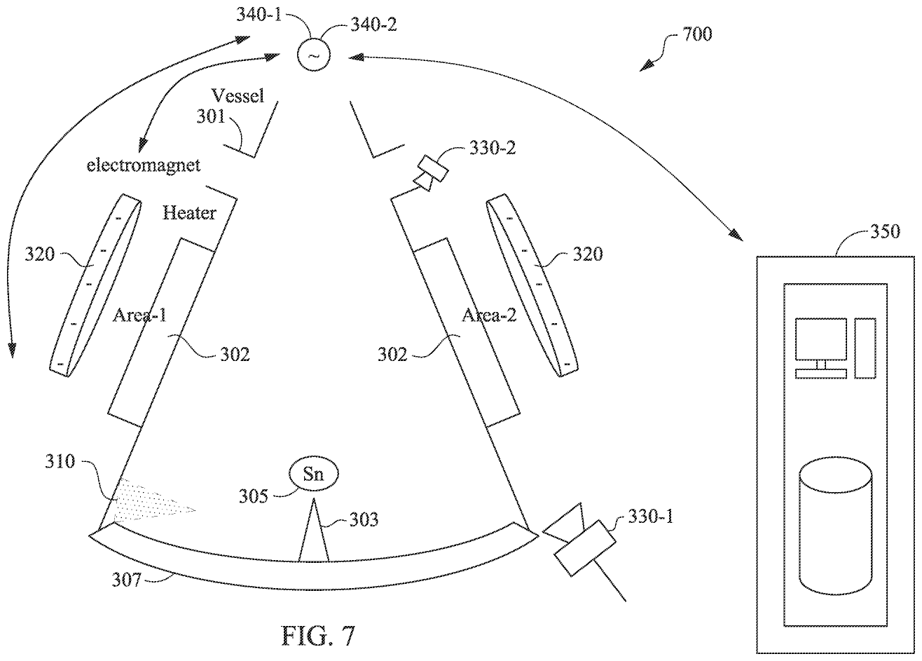

FIG. 7 is a simplified schematic diagram illustrating an apparatus 700 for extreme ultraviolet lithography, according to some embodiments. As shown in FIG. 7, apparatus 700 is a radiation source (also referred to as radiation source 700) that can be used in an EUV lithography system like the EUV lithography system 10 shown in FIG. 1. Radiation source 700 has similar components as radiation source 600 described above in connection to FIG. 6, and these components are labeled with the same reference numerals.

In addition, radiation source 700 further includes a database 350 that includes, among other information, Sn debris morphologies and heater temperature conditions. The database 350 may be a server physically located in close proximity to the radiation source 700 in some embodiments. In other embodiments, the database 350 may be a server located remotely (e.g., outside the semiconductor fabrication facility or foundry where the radiation source 700 is located), and the database 350 is accessible through wired or wireless communication. The database 350 contains information accessible by the radiation source 700 used in, for example, the EUV lithography system 10 shown in FIG. 1. In some embodiments, the information included in the database 350 includes information regarding tin (Sn) debris morphologies and heater temperature conditions. In other embodiments, the information included in the database 350 may further include information regarding the supplemental laser source 310. In other embodiments, the information included in the database 350 may further include information regarding the first laser source 303. In yet other embodiments, the information included in the database 350 may further include information regarding the plasma quality (e.g., plasma density, plasma temperature, thickness of the plasma sheath, and the like) generated in the vessel 301. The database 350 can include historical data collected from the same radiation source 700 used in, for example, the EUV lithography system 10 shown in FIG. 1. By way of using the historical data, a machine learning model can be used to adjust various parameters of the radiation source 700 used in, for example, the EUV lithography system 10 so that less Sn debris is accumulated.

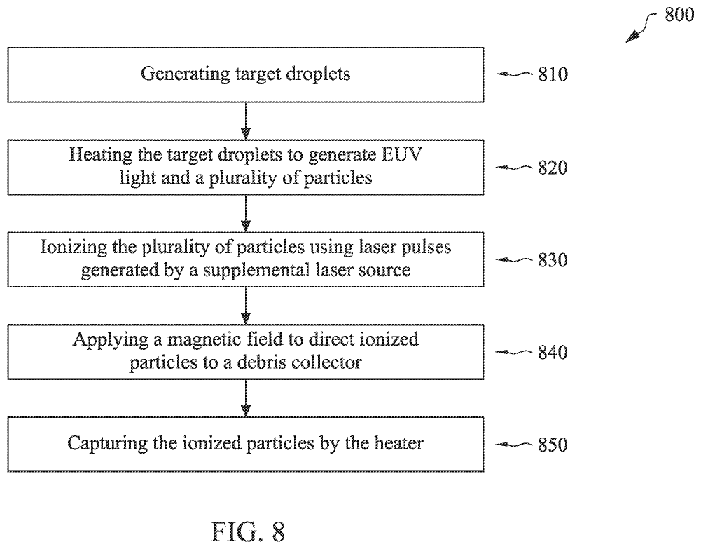

FIG. 8 is a simplified flowchart illustrating a method for extreme ultraviolet (EUV) lithography, according to some embodiments. As shown in the flowchart of FIG. 8, the method 800 include operations 810, 820, 830, 840, and 850. Additional operations may be performed. Also, it should be understood that the sequence of the various operations discussed above with reference to FIG. 8 is provided for illustrative purposes, and as such, other embodiments may utilize different sequences. These various sequences of operations are to be included within the scope of embodiments.

At operation 810, target droplets are generated. In one embodiment, a target droplet generator (e.g., the target droplet generator 115 shown in FIG. 1) generates a plurality of target droplets (e.g., the target droplets 116 shown in FIG. 1). In some embodiments, the target droplets 116 are tin (Sn) droplets. In some embodiments, the target droplets 116 have a diameter of about 30 micrometers (μm). Other materials may also be used for the target droplets 116, for example, liquid materials such as eutectic alloys containing Sn and lithium (Li).

At operation 820, the target droplets are heated to generate EUV light and a plurality of particles. When the main pulse (e.g., the main pulse 232 shown in FIG. 1) heats the target plume, a high temperature plasma is generated. As a result, the laser-produced plasma emits EUV radiation or EUV light, which is collected by one or more mirrors of the laser-produced plasma collector (e.g, the laser-produced plasma collector 110 shown in FIG. 1). Sn particles (e.g., the Sn particles 311) remain in the vessel (e.g., the vessel 301 shown in FIG. 4).

At operation 830, the plurality of particles are ionized using laser pulses generated by a supplemental laser source (e.g., the supplemental laser source 310 shown in FIG. 4). The Sn particles 311 would otherwise remain not ionized without the supplemental laser source 310. Therefore, the laser pulses generated by the supplemental laser source 310 can increase the percentage of Sn particles 311 that are ionized, thereby reducing the percentage of Sn particles that are not ionized.

At operation 840, a magnetic field is applied to directed ionized particles (e.g., the Sn ions 312 shown in FIG. 4) to a debris collector (e.g., the heaters 302 shown in FIG. 4). The Sn ions 312 are directed to the heaters 302. In one implementation, the magnetic field is generated by the magnetic source 320 shown in FIG. 4, which includes at least one coil of wire with electric current running through it. By fine-tuning the electric current, the amplitude of the magnetic field generated by the magnetic source 320 shown in FIG. 4 is adjusted accordingly, so that a large portion of the Sn ions (e.g., Sn ions 312 shown in FIG. 4) are directed toward the heaters 302.

At operation 850, the ionized particles (e.g., the Sn ions 312 shown in FIG. 4) are captured by debris collector (e.g., the heaters 302 shown in FIG. 4). In some embodiments, the heater 302 shown in FIG. 4 generates heat to vaporize the Sn particles 311 (Sn ions 312 become Sn particles 311 after they hit the chamber sidewall or the vessel 301) at close proximity to the heater 302, thereby facilitating the reflux of the Sn particles 311. As a result, the amount of Sn particles 311 accumulated on the chamber walls or the vessel 301 is reduced, leading to reduced Sn debris.

In some embodiments, the particles comprise Tin (Sn) debris. In some embodiments, the method also includes monitoring the particles using an imaging device (e.g., the CCD module 330 shown in FIG. 5). In some embodiments, the method also includes managing the magnetic field based on the feedback information from the supplemental laser source (e.g., the supplemental laser source 310 shown in FIG. 5) and CCD module 330.

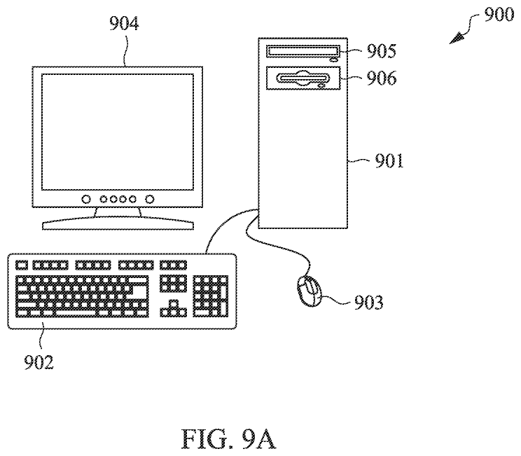

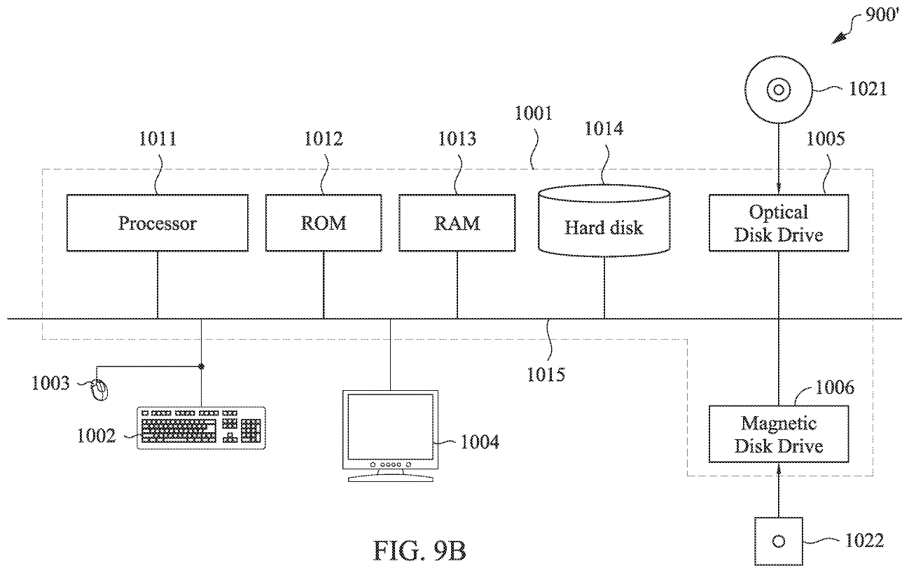

FIGS. 9A and 9B illustrate a computer system 900 for controlling a lithography system, such as the EUV lithography system 10 depicted in FIG. 1 and radiation sources depicted in FIGS. 2-7 and their components according to various embodiments of the present disclosure. FIG. 9A is a schematic diagram of a computer system 900. In some embodiments, the computer system 900 is programmed to initiate a process for monitoring the contamination level of or resulting from a chamber component, such as radiation sources depicted in FIGS. 2-7. The computer system 900 is also programmed to build the database 350 depicted in FIG. 7. As illustrated in FIG. 9A, a computer system 900 is provided with a computer 901 that includes an optical disk read-only memory (e.g., CD-ROM or DVD-ROM) drive 905, and a disk drive 906, a keyboard 902, a mouse 903 (or other similar input device), and a monitor 904.

FIG. 9B is a schematic diagram illustrating an internal configuration of the computer system 900′. In FIG. 9B, in addition to the optical disk drive 1005 and the magnetic disk drive 1006, the computer 1001 is also provided with one or more processors 1011, such as a Micro Processing Unit (MPU) or a Central Processing Unit (CPU); a read only memory 1012 in which programs such as a boot program are stored; a Random Access Memory (RAM) 1013 connected to the MPU 1011 and providing a temporary electronic storage area in which instructions of application programs that are temporarily stored and data are temporarily stored; a hard disk 1014 in which application programs, operating system programs, and data are stored; and a communication bus 1015 connecting the MPU 1011, the ROM 1012, and the like. Note that computer 1001 may include a network card (not shown) for providing a connection to a computer network, such as a Local Area Network (LAN), wide Area Network (WAN), or any other useful computer network for communicating data used by computer system 900′.

Programs for causing the computer system 900′ to perform processes of the EUV lithography system 10 shown in FIG. 1, the controller 90 shown in FIG. 2, the electromagnet management module 340 shown in FIGS. 5-7 and components thereof and/or processes for performing methods of manufacturing semiconductor devices according to embodiments disclosed herein are stored in the optical disk 1021 or the magnetic disk 1022, inserted into the optical disk drive 1005 or the magnetic disk drive 1006, respectively, and transferred to the hard disk 1014. Alternatively, the program may be transferred to the computer system 900′ via a network (not shown) and stored on the hard disk 1014. At the time of execution, the program is loaded into the RAM 1013. In various embodiments, the program may be loaded from the optical disk 1021 or the magnetic disk 1022 or directly from the network. The computer system 900′ further includes a mouse 1003, a keyboard 1002, and a monitor 1004.

The stored programs do not necessarily include, for example, an Operating System (OS) or a third party program to cause the computer 1001 to perform the methods disclosed herein. In some embodiments, a program may contain only an instruction portion to invoke the appropriate function (module) in a controlled mode and obtain a satisfactory result. In various embodiments described herein, the computer system 900′ communicates with the EUV lithography system 10 shown in FIG. 1 to control various functions thereof.

In various embodiments, the computer system 900′ is coupled to the EUV lithography system 10 shown in FIG. 1. The computer system 900′ is configured to provide control data to and receive process and/or status data from these system components. For example, the computer system 900′ includes a microprocessor, memory (e.g., volatile or non-volatile memory), and a digital I/O port capable of generating control voltages sufficient to communicate with the EUV lithography system 10 shown in FIG. 1 and activate inputs, and monitor outputs from the EUV lithography system 10. In addition, the programs stored in the memory are utilized to control the components of the EUV lithography system 10 described above according to a process recipe. Further, the computer system 900′ is configured to analyze the process and/or status data, to compare the process and/or status data to target process and/or status data, and to use the comparison to change process and/or control system components. Further, the computer system 900′ is configured to analyze the process and/or status data, compare the process and/or status data to historical process and/or status data, and use this comparison to predict, prevent, and/or declare a fault or alarm.

Extreme Ultraviolet (EUV) lithography systems are critical to advance semiconductor manufacturing. In EUV lithography, a laser beam is focused on small fuel droplet targets of tin (Sn) in order to convert them into a highly ionized plasma state. The laser-generated plasma emits extreme ultraviolet light. Tin debris is generated during this process, which can adversely affect the performance and efficiency of the EUV apparatus. Various embodiments apply additional laser beams to ionize the tin debris and use a magnetic field to direct the ionized tin debris for collection. These measures can reduce tin contamination on the EUV vessel, such as the collector and caps, reduce the repair cost and improve the efficiency of the EUV tool. In addition, mask defects cause by tin contamination is also reduced, preventing wafer defects and product yield loss.

An apparatus for extreme ultraviolet lithography includes a target droplet generator configured to generate target droplets and a first laser source configured to generate first laser pulses and second laser pulses, respectively, that heat the target droplets to produce extreme ultraviolet (EUV) light and a plurality of particles that contain tin (Sn) debris. The apparatus also includes a heater that also functions as a debris collector, a supplemental laser source to generate third laser pulses to ionize the plurality of particles, and an electromagnet configured to generate a magnetic field to direct ionized particles to the heater for collection. The apparatus also includes an imaging device for monitoring the tin debris and a control system configured to control the supplemental laser source and the electromagnet based on feedback information from pulsed laser and imaging device feedback by area.

In some embodiments of the above apparatus, the imaging device includes one or more charge-coupled device (CCD) modules. In some embodiments, the control system also includes one or more electromagnet management modules. In some embodiments, the third laser source is a CO2 laser source. In some embodiments, the apparatus includes a database that contains information regarding tin (Sn) debris morphologies and heater temperature conditions.

According to some embodiments, an apparatus for extreme ultraviolet lithography includes a target droplet generator configured to generate target droplets, a first laser source configured to generate laser pulses that heat the target droplets to produce extreme ultraviolet (EUV) light and a plurality of particles. The apparatus also includes a heater, a supplemental laser source configured to generate laser pulses to ionize the plurality of particles, and an electromagnet configured to generate a magnetic field to direct ionized particles to the heater for collection. In some embodiments, the particles comprise tin debris. In some embodiments, the apparatus also includes an imaging device for monitoring the tin debris. In some cases, the imaging device includes a CCD (charge-coupled device) module. In other cases, the imaging device can include two CCD modules. In some embodiments, the apparatus also includes a control system. In some examples, the control system also includes an electromagnet management module. In other examples, the control system can include two or more electromagnet management modules. In some embodiments, the control system is configured to manage the electromagnet based on feedback information from the pulsed laser and CCD module feedback by area. In some embodiments, the target droplet generator comprises a radiation source that generates laser pulses including a pre-pulse and a main pulse. In some embodiments, the apparatus also includes a database that contains information regarding Tin (Sn) debris morphologies and heater temperature conditions.

According to some embodiments, a method for extreme ultraviolet (EUV) lithography includes generating target droplets and using a first laser source to generate laser pulses to heat the target droplets to generate extreme ultraviolet (EUV) light and a plurality of particles. The method also includes using a second laser source to generate laser pulses to ionize the plurality of particles, applying a magnetic field to direct ionized particles to debris collection device, and capturing the ionized particles by the debris collection device. In some embodiments of the method, the particles include tin (Sn) debris. In some embodiments, the method also includes monitoring the particles using an imaging device. In some embodiments, the method also includes managing the magnetic field based on the feedback information from the pulsed laser and CCD module feedback by area.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An apparatus for extreme ultraviolet lithography, comprising:
a target droplet generator configured to generate target droplets;
a first laser source configured to generate first laser pulses and second laser pulses, respectively, that heat the target droplets to produce extreme ultraviolet (EUV) light and a plurality of particles that contain tin (Sn) debris;
a heater that also functions as a debris collector;
a supplemental laser source to generate third laser pulses to ionize the plurality of particles;
an electromagnet configured to generate a magnetic field to direct ionized particles to the heater for collection;
an imaging device for monitoring the tin debris, and
a control system configured to control the supplemental laser source and the electromagnet based on feedback information from the supplemental laser source and the imaging device.

2. The apparatus of claim 1, wherein the imaging device comprises one or more charge-coupled device (CCD) modules.

3. The apparatus of claim 1, wherein the control system further comprises one or more electromagnet management modules.

4. The apparatus of claim 1, wherein the supplemental laser source is a CO2 laser source.

5. The apparatus of claim 1, further comprising a database that contains information regarding tin (Sn) debris morphologies and heater temperature conditions.

6. An apparatus for extreme ultraviolet lithography, comprising:
a target droplet generator configured to generate target droplets;
a first laser source configured to generate laser pulses that heat the target droplets to produce extreme ultraviolet (EUV) light and a plurality of particles;
a heater;
a supplemental laser source configured to generate laser pulses to ionize the plurality of particles; and
an electromagnet configured to generate a magnetic field to direct ionized particles to the heater for collection.

7. The apparatus of claim 6, wherein the particles comprise tin debris.

8. The apparatus of claim 7, further comprising an imaging device for monitoring the tin debris.

9. The apparatus of claim 8, wherein the imaging device comprises a CCD module.

10. The apparatus of claim 8, wherein the imaging device comprises two CCD modules.

11. The apparatus of claim 8, further comprising a control system.

12. The apparatus of claim 11, wherein the control system further comprises an electromagnet management module.

13. The apparatus of claim 11, wherein the control system further comprises two electromagnet management modules.

14. The apparatus of claim 11, where the control system is configured to manage the electromagnet based on feedback information from the supplemental laser source and a CCD module.

15. The apparatus of claim 6, wherein the target droplet generator comprises a radiation source that generates laser pulses including a pre-pulse and a main pulse.

16. The apparatus of claim 11, further comprising a database that contains information regarding Tin (Sn) debris morphologies and heater temperature conditions.

17. A method for extreme ultraviolet (EUV) lithography, the method comprising:
generating target droplets;
using a first laser source to generate first laser pulses to heat the target droplets to generate extreme ultraviolet (EUV) light and a plurality of particles;
using a supplemental laser source to generate second laser pulses to ionize the plurality of particles;
applying a magnetic field to direct ionized particles to a debris collection device; and
capturing the ionized particles by the debris collection device.

18. The method of claim 17, wherein the particles comprise tin (Sn) debris.

19. The method of claim 17, further comprising monitoring the particles using an imaging device.

20. The method of claim 19, further comprising managing the magnetic field based on feedback information from the supplemental laser source and the imaging device.
